(19) United States
(12) Patent Application Publication
(10) Pub. No.: US 2025/0203831 A1
(43) Pub. Date: Jun. 19, 2025

(54) DISPLAY APPARATUS

(71) Applicant: LG Display Co., Ltd., Seoul (KR)

(72) Inventor: Kyoung-hoon KIM, Gumi-si (KR)

(21) Appl. No.: 18/909,523

(22) Filed: Oct. 8, 2024

(30) Foreign Application Priority Data
Dec. 13, 2023 (KR) 10-2023-0181190

(51) Int. Cl. H05K 9/00; B60K 35/22; B60K 37/10; H05K 1/18

(52) U.S. Cl. CPC H05K 9/0054; B60K 35/22; B60K 37/10; H05K 1/189; H05K 2201/10128

(57) ABSTRACT

A display apparatus according to one embodiment may include a display panel on which a video is displayed, a metal plate disposed behind the display panel, a first circuit board disposed behind the metal plate and electrically connected to the display panel, a chip on film (COF) having one side electrically connected to the display panel, the other side electrically connected to the first circuit board, and a portion provided to be bent, and a front cover disposed in front of the first circuit board and vertically disposed to be spaced apart from the display panel, in which an upper area in front of the first circuit board may be coupled to the metal plate, and a lower area thereof may be coupled to the front cover.

### CROSS REFERENCE TO RELATED APPLICATION

The present application claims priority to Korean Patent Application No. 10-2023-0181190, filed Dec. 13, 2023, the entire contents of which is incorporated herein for all purposes by this reference.

### BACKGROUND

### Technical Field

The present disclosure relates to a display apparatus, and more specifically, to a display apparatus having a slim structure in appearance and a structure having an improved aesthetic sense in design.

### Description of the Related Art

Contents described in this section simply provide background information on the present disclosure and do not constitute the related art.

In the full-fledged information age, the field of display apparatuses for visually displaying electrical information signals is developing rapidly, and research for developing performance, such as thinness, lightweight, and lower power consumption, for various display apparatuses is being continuously conducted.

Such display apparatuses include a liquid crystal display (LCD) device, a quantum dot display panel device (QD), a field emission display (FED) device, and an electro-wetting display (EWD) device, an organic light emitting diode (OLED) display apparatus, etc.

The display apparatuses have been developed to be miniaturized so that users may carry the display apparatuses or to be mounted on movable devices such as vehicles, etc., and are being improved so that the users may use the display apparatuses more conveniently.

### BRIEF SUMMARY

In general, display apparatuses need to be manufactured in a slim form having a small thickness to satisfy a user's aesthetic sense in design. However, a printed circuit board provided in the display apparatus may be provided with an element having a predetermined volume.

For example, in the case of a heating element that requires a relatively large amount of electricity to operate in the display apparatus, a significant heating quantity is generated by the operation as an active element, and the volume may be relatively great.

There may be limits to reducing the thickness of the display apparatus that accommodates such a large-volume heating element. However, to satisfy the user's design needs, a portion visible to the user needs to be formed at least in a slim structure in the display apparatus.

For example, when a portion on which a bulky device is disposed is disposed above a dashboard of a vehicle, the display apparatus mounted on the dashboard may have a significantly greater thickness in the portion in which the bulky device is disposed than other portions.

Therefore, the display apparatus having such a structure may have poor aesthetic sense in design. Therefore, there is a need to develop a display apparatus having a structure in which the portion in which the bulky device may be disposed under the dashboard of the vehicle.

Meanwhile, the heating element may be disposed to be spaced apart from the display panel with a metal plate provided for heat dissipation interposed therebetween. Therefore, the heat generated from the heating element may be transferred to the metal plate by conduction, radiation, or convection and dissipated to the outside from the metal plate.

However, the metal plate cannot fully dissipate the heat received from the heating element to the outside, and thus the heat generated from the heating element may be transferred to the display panel through the metal plate through conduction, convection, and radiation.

Therefore, when the heat generated from the heating element is transferred to the display panel, a temperature of the display panel may increase, and a continuous increase in the temperature may cause damage to the display panel, shortening lifetime, etc., due to degradation.

Therefore, there is a need to develop a display apparatus having a structure that can suppress the heat generated from the heating element from being transferred to the display panel.

Therefore, the present disclosure is directed to providing a display apparatus having a slim structure in appearance and having a structure having an improved aesthetic sense in design.

In addition, the present disclosure is directed to providing a display apparatus having a slim structure in appearance by arranging a thick portion under a dashboard of a vehicle, that is, at the bottom of the dashboard.

In addition, the present disclosure is directed to providing a display apparatus having a structure that can suppress heat generated from a heating element provided on a printed circuit board from being transferred to a display panel.

Objects of the present disclosure are not limited to the above-described objects, and other objects and advantages of the present disclosure which are not mentioned can be understood by the following description and more clearly understood by embodiments of the present disclosure. In addition, it will be able to be easily seen that the objects and advantages of the present disclosure may be achieved by devices and combinations thereof that are described herein.

A display apparatus according to one embodiment may include a display panel on which a video is displayed, a metal plate disposed behind the display panel, a first circuit board disposed behind the metal plate and electrically connected to the display panel, and a front cover disposed in front of the first circuit board and vertically disposed to be spaced apart from the display panel.

An upper area in front of the first circuit board may be coupled to the metal plate, and a lower area thereof may be coupled to the front cover.

The first circuit board may include a first area having a relatively small thickness and a second area having a relatively great thickness, wherein at least a portion of the first area may overlap the display panel in the front-rear direction, and the second area may be disposed to overlap the front cover in the front-rear direction.

The display apparatus may include a back cover of which at least a portion is disposed behind the display panel and the first circuit board, and the back cover may include an accommodation part configured to accommodate the second area of the first circuit board.

The display apparatus may be provided to be mounted on a dashboard of a vehicle, and the second area and the accommodation part may be disposed inside the dashboard.

A display apparatus according to another embodiment may include a second circuit board electrically connected to the first circuit board, a chip on film (COF) having one side electrically connected to the display panel and the other side electrically connected to the first circuit board, and a portion provided to be bent, a front cover disposed in front of the first circuit board and vertically disposed to be spaced apart from the display panel, and a back cover of which at least a portion is disposed behind the display panel and the first circuit board.

An upper area in front of the first circuit board may be disposed to overlap the display panel in a front-rear direction, and the lower area thereof may be disposed to overlap the front cover in the front-rear direction.

The display apparatus may be provided to be mounted on a dashboard of a vehicle, and an upper cover of the dashboard may be vertically disposed between the accommodation part and the display panel.

### BRIEF DESCRIPTION OF THE SEVERAL VIEWS OF THE DRAWINGS

FIG. 1 is a perspective view showing a display apparatus according to one embodiment.

FIG. 2 is a perspective view of FIG. 1 in another direction.

FIG. 3 is a side view showing a portion of the display apparatus according to one embodiment.

FIG. 4 is an exploded view showing the display apparatus according to one embodiment.

FIG. 5 is a side cross-sectional view showing a portion of the display apparatus according to one embodiment.

FIG. 6 is an enlarged view showing portion A in FIG. 5.

FIG. 7 is an enlarged view showing portion B in FIG. 5.

FIG. 8 is a perspective view showing a state in which the display apparatus according to one embodiment is mounted on a dashboard of a vehicle.

FIG. 9 is a side cross-sectional view schematically showing the display apparatus according to one embodiment.

FIG. 10 is a view showing a state in which a chip on film is unfolded in the display apparatus according to one embodiment.

FIG. 11 is a view showing a state in which a first circuit board and a metal plate are coupled in the display apparatus according to one embodiment.

FIG. 12 is a perspective view of FIG. 11.

### DETAILED DESCRIPTION

The above-described objects, features, and advantages will be described below in detail with reference to the accompanying drawings, and thus those skilled in the art to which the present disclosure pertains will be able to easily carry out the technical spirit of the present disclosure. In describing the present disclosure, when it is determined that a detailed description of the known technology related to the present disclosure may unnecessarily obscure the gist of the present disclosure, a detailed description thereof will be omitted. Hereinafter, exemplary embodiments according to the present disclosure will be described in detail with reference to the accompanying drawings. In the drawings, the same reference numerals are used to denote the same or similar components.

Although terms such as first and second are used to describe various components, it goes without saying that the components are not limited by these terms. These terms are only used to distinguish one component from another component, and unless otherwise stated, it goes without saying that the first component may be the second component.

Throughout the specification, unless otherwise stated, each component may be singular or plural.

The singular expression used herein includes the plural expression unless the context clearly dictates otherwise. In the application, terms such as “composed of” or “comprising” should not be construed as necessarily including all of the various components or operations described in the specification and should be construed as not including some of the components or some of the operations or further including additional components or operations.

Throughout the specification, when “A and/or B” is described, this means A, B, or A and B unless otherwise specified, and when “C to D” is described, this means C or more and D or less unless otherwise specified.

In the following description, when a user views a display apparatus 100 in a state in which the display apparatus 100 is disposed to be generally used, a direction in which the user is located is referred to as “forward,” and a direction opposite to the forward is referred to as “backward.”

In addition, “vertically,” “upper side,” “lower side,” “above,” “under” indicates a location or direction of each component in a state in which the display apparatus is disposed to be generally used. In the drawing, “forward” indicates a +X-axis direction, “backward” indicates a −X-axis direction, and “vertically” indicates a Z-axis direction.

The display apparatus according to the embodiment may be mounted, for example, in a cockpit of a vehicle to provide a video or image required for driving to a driver and a passenger of the vehicle. However, the present disclosure is not limited thereto, and the display apparatus may be used while carried by the user rather than mounted on the vehicle. Hereinafter, for example, a display apparatus mounted on a vehicle will be described.

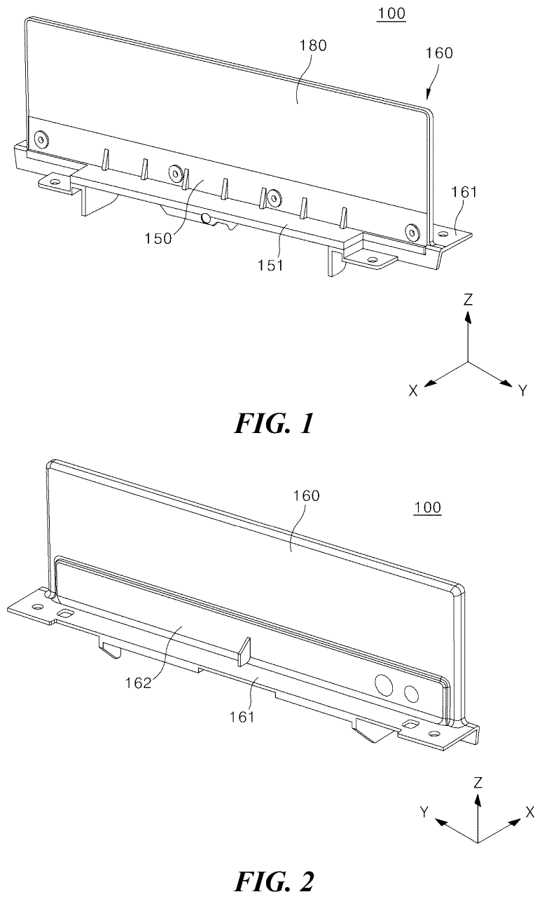

FIG. 1 is a perspective view showing the display apparatus 100 according to one embodiment. FIG. 2 is a perspective view of FIG. 1 in another direction.

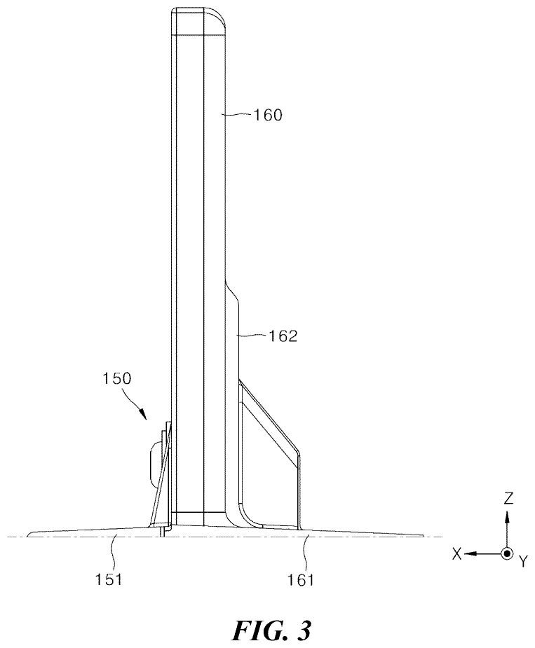

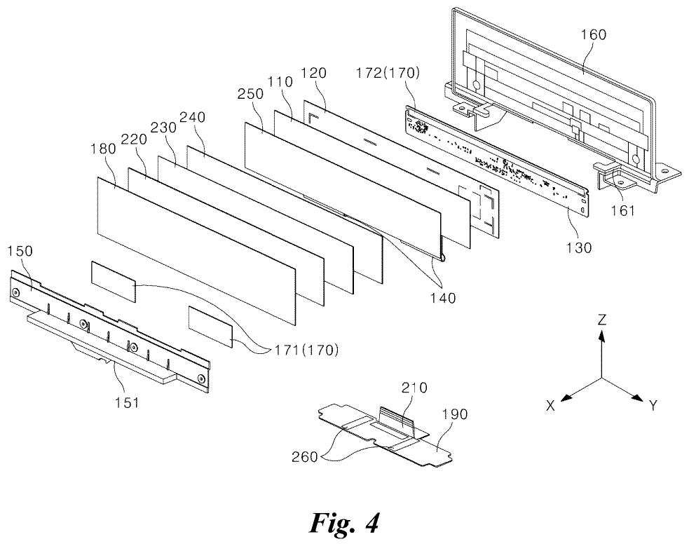

FIG. 3 is a side view showing a portion of the display apparatus 100 according to one embodiment. FIG. 4 is an exploded view showing the display apparatus 100 according to one embodiment.

The display apparatus 100 according to the embodiment may include a display panel 110, a metal plate 120, a first circuit board 130, a chip on film (COF) 140, and a front cover 150.

A video or image may be displayed on the display panel 110. The video or image to be displayed may be navigation information necessary for traveling, video captured by a camera mounted on the vehicle, or various other contents needed by a driver or passengers.

The metal plate 120 may be disposed behind the display panel 110. The metal plate 120 may serve as a heat sink for cooling the display panel 110 by dissipating heat generated from the display panel to the outside.

The metal plate 120 may be made of, for example, aluminum, copper, or a metal material containing the same, which has a high heat transfer rate. However, the present disclose is not limited thereto.

The first circuit board 130 may be disposed behind the metal plate 120 and electrically connected to the display panel 110. The first circuit board 130 may have various circuit components mounted thereon and may be electrically connected to the second circuit board 190 to receive electricity from the second circuit board 190.

In addition, the first circuit board 130 may transmit an operation signal to the chip on film 140 and the display panel 110 to control an operation of the display panel 110 and supply electricity to the chip on film 140 and the display panel 110.

The printed circuit board 130 may include a camera, a device for communicating with external devices such as a main control module of a vehicle, a device for driving the display panel 110 so that the display panel 110 displays a video or image, etc., and provided with a circuit and various other active and passive elements.

The chip on film 140 may have one side electrically connected to the display panel 110, the other side electrically connected to the first circuit board 130, and a portion provided to be bent. The chip on film 140 may be disposed so that a portion is bent to surround an end portion of the metal plate 120.

The chip on film 140 may be formed thinly and made of a flexible material to enable bending. The chip on film 140 may electrically connect the display panel 110 with the first circuit board 130. The chip on film 140 may be provided with various active and passive elements and provided with a driving circuit for driving the display panel 110.

The driving circuit for driving the display panel 110 may be provided to be dispersed to each of the first circuit board 130 and the chip on film 140. The chip on film 140 may be provided with a driving element that forms at least a portion of the driving circuit of the display panel 110. A plurality of chip on films 140 may be provided. The chip on films 140 may be disposed to be spaced apart from each other.

The front cover 150 may be disposed in front of the first circuit board 130 and disposed to be vertically spaced apart from the display panel 110. The front cover 150 may store at least some of various components of the display apparatus 100 and form a portion of the appearance of the display apparatus 100.

Since the display panel 110 is disposed not to be covered by the front cover 150 so as to be visible to the user, the front cover 150 may be disposed to be vertically spaced apart from the display panel 110.

The display apparatus 100 may include a back cover 160, an adhesive part 170, and a cover member 180. At least a portion of the back cover 160 may be disposed behind the display panel 110 and the first circuit board 130. The back cover 160 may be coupled with the front cover 150.

The back cover 160, together with the front cover 150 may store at least some of various components of the display apparatus 100 and form a portion of the appearance of the display apparatus 100. The back cover 160 may be provided to cover the entirety of a rear portion of the display apparatus 100 to protect other components included in the display apparatus 100.

The adhesive part 170 couples the first circuit board 130 to other components of the display apparatus 100 and may include a first part 171 and a second part 172.

The first part 171 may be disposed between the front cover 150 and the first circuit board 130 to couple the front cover 150 to the first circuit board 130. A plurality of first parts 171 may be disposed to be spaced apart from each other.

The second part 172 may be disposed between the first circuit board 130 and the metal plate 120 to couple the first circuit board 130 to the metal plate 120. The second part 172 may be disposed parallel with a longitudinal direction of the first circuit board 130 and attached to an upper portion of the first circuit board 130.

The adhesive part 170 may be provided in a film or plate shape and made of an adhesive material. The adhesive part 170 may be made of or include a material that is transparent and has good adhesion, such as the an optical clear adhesive (OCA), an optical clear resin (OCR), or a pressure sensitive adhesive (PSA).

The cover member 180 may be disposed in front of the display panel 110. The cover member 180 may be disposed at the frontmost portion of the display apparatus 100. The cover member 180 may be disposed in front of the display panel 110 to protect the display panel 110. The cover member 180 may be made of a transparent material to allow light emitted from the display panel 110 to pass through the cover member 180.

The cover member 180 may be coupled with the front cover 150. Since the user views the displayed screen through the light emitted from the cover member 180, the front cover 150 may be disposed under the cover member 180 to prevent the front cover 150 from interfering with the displayed screen.

The display apparatus 100 may include a second circuit board 190 and a flexible circuit board 210. The second circuit board 190 may be electrically connected to the first circuit board 130 and disposed under the display apparatus 100.

The second circuit board 190 may connect a controller provided in the vehicle to the first circuit board 130 to supply electricity to the first circuit board 130. The second circuit board 190 may be provided with various active elements, passive elements, and electric circuits to play its role.

The flexible circuit board 210 may electrically connect the first circuit board 130 to the second circuit board 190. The flexible circuit board 210 may be made of a flexible material so that arrangement locations and arrangement shapes of the first circuit board 130 and the second circuit board 190 may be freely adjusted. The flexible circuit board 210 may be provided with various active elements, passive elements, and electric circuits to play its role.

The display apparatus 100 may include a first adhesive layer 220, a light control layer 230, a second adhesive layer 240, a polarizer 250, and an adhesive tape 260.

The first adhesive layer 220 may be disposed between the cover member 180 and the light control layer 230 to couple the cover member 180 to the light control layer 230. The first adhesive layer 220 may allow light emitted from the display panel 110 to pass therethrough, and thus may be made of a transparent material.

Therefore, the first adhesive layer 220 may be made of or include a material that is transparent and has good adhesive strength, such as the OCA, the OCR, or the PSA.

The light control layer 230 may be disposed between the display panel 110 and the cover member 180. The light control layer 230 may adjust a direction of light emitted from the display panel 110 and passing therethrough, and thus may adjust a viewing angle of the display screen visible to the user. The light control layer 230 may be manufactured, for example, in the form of a light control film (LCF), which is the form of a thin film.

The second adhesive layer 240 may be disposed between the light control layer 230 and the polarizer 250 to couple the light control layer 230 to the polarizer 250. Like the first adhesive layer 220, the second adhesive layer 240 may allow the light emitted from the display panel 110 to pass therethrough, and may be made of a transparent material.

Therefore, the second adhesive layer 240 may be made of or include a material that is transparent and has good adhesive strength, such as the OCA, the OCR, or the PSA.

The polarizer 250 may be disposed between the display panel 110 and the light control layer 230. The polarizer 250 may convert the light radiated from the display panel 110 into circularly polarized light. The polarizer 250 can increase outdoor visibility and contrast ratio for images displayed on the display panel 110 by preventing reflection of external light.

The adhesive tape 260 may attach the second circuit board 190 to the front cover 150 and the back cover 160. A plurality of adhesive tapes 260 may be provided, disposed at locations spaced apart from each other, and attached to the second circuit board 190. The adhesive tape 260 may be a double-sided tape having good adhesiveness.

In general, display apparatuses need to be manufactured in a slim form having a small thickness to satisfy a user's aesthetic sense in design. However, the printed circuit board provided in the display apparatus, that is, the first circuit board 130 in the embodiment, may be provided with an element having a predetermined volume.

For example, in the case of the display apparatus 100 of the embodiment, the heating element 133, which requires a relatively large amount of electricity to operate, is an active element and may generate a significant heat quantity during operation and have a relatively great volume.

The heating element 133 may be, for example, at least one of a light emitting module using an LED as a light source, a CPU for controlling the operation of the display panel, and a capacitor.

There may be a limit to reducing the thickness of the display apparatus 100 that accommodates the bulky heating element 133. However, to satisfy the user's design needs, at least a portion of the display apparatus 100, which is visible to the user, needs to be manufactured in a slim structure.

For example, when a portion in which the bulky element is disposed is disposed above a dashboard 10 of a vehicle, in the display apparatus 100 mounted on the dashboard 10, the portion in which the bulky element is disposed may have a much greater thickness than other portions.

Therefore, the display apparatus 100 having such a structure may have poor aesthetic sense in design. Therefore, there is a need to develop the display apparatus 100 having a structure in which the portion in which the bulky device is disposed may be disposed under the dashboard 10 of the vehicle.

Meanwhile, the heating element 133 may be disposed to be spaced apart from the display panel 110 with the metal plate 120 provided for heat dissipation interposed therebetween. Therefore, the heat generated from the heating element 133 may be transferred to the metal plate 120 by conduction, radiation, or convection and dissipated to the outside from the metal plate 120.

However, the metal plate 120 cannot completely dissipate the heat received from the heating element 133 to the outside, and thus the heat generated from the heating element 133 may pass through the metal plate 120 and may be transferred to the display panel 110 through conduction, convection, and radiation.

Therefore, when the heat generated from the heating element 133 is transferred to the display panel 110, the temperature of the display panel 110 increases, and the continuous increase in temperature may cause damage to the display panel 110 due to deterioration, a decrease in lifespan, etc.

Therefore, there is a need to develop the display apparatus 100 having a structure that can suppress the heat generated from the heating element 133 from being transferred to the display panel 110.

Hereinafter, a structure according to the embodiment, in which the portion viewed by the user is slimmed to improve the aesthetic sense in design and the transfer of the heat generated from the heating element 133 to the display panel 110 can be suppressed will be described in detail.

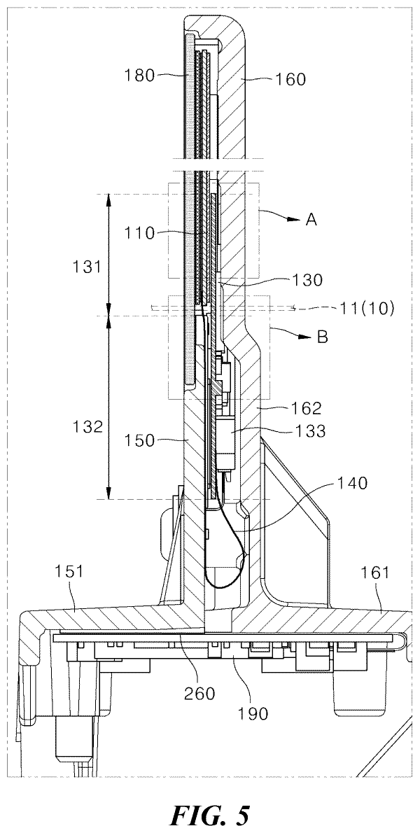

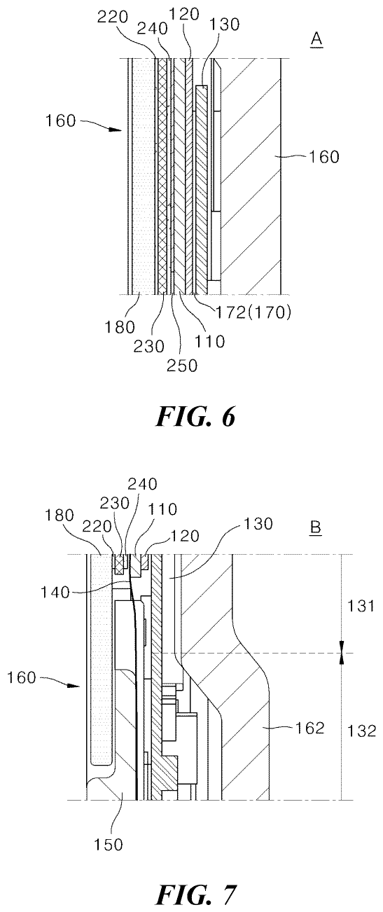

FIG. 5 is a side cross-sectional view showing a portion of the display apparatus 100 according to one embodiment. FIG. 6 is an enlarged view showing portion A in FIG. 5. FIG. 7 is an enlarged view showing portion B in FIG. 5.

The first circuit board 130 may include a first area 131 having a relatively small thickness and a second area 132 having a relatively great thickness. The heating element 133 having a higher heat quantity than other elements constituting the first circuit board 130 may be disposed in the second area 132.

The heating element 133 is an element provided to control the operation of the display panel 110 and may be provided to generate heat and have a predetermined volume. Therefore, the heating element 133 may have a relatively great volume compared to other elements.

Therefore, the second area 132 in which the heating element 133 is disposed may have a greater thickness than the first area 131 due to the volume of the heating element. Due to the presence of the second area 132, the back cover 160 may be thicker in the portion in which the second area 132 is accommodated than in other areas.

That is, the back cover 160 may include an accommodation part 162 for accommodating the second area 132 of the first circuit board 130, and the accommodation part 162 may have a greater thickness than other portions of the back cover 160.

Specifically, the accommodation part 162 may be formed to have a portion corresponding to the second area 132 of the back cover 160, which protrudes from a rear surface of the back cover 160 and is recessed in a front surface of the back cover 160.

Therefore, in the display apparatus 100, the second area 132 of the first circuit board 130 and the accommodation part 162 of the back cover 160 disposed at the corresponding location may be formed to have a greater thickness than other parts of the display apparatus 100.

Meanwhile, the chip on film 140 needs to extend to have an appropriate length to electrically connect the first circuit board 130 to the display panel 110 and to be disposed without interfering with other components in the display apparatus 100.

To this end, the chip on film 140 may have one side coupled to a lower portion of the first circuit board 130 and the other side coupled to a lower portion of the display panel 110 and may be disposed to vertically intersect the second area 132. In addition, at least a portion of the chip on film 140 may be disposed between the front cover 150 and the first circuit board 130.

With this arrangement structure, the chip on film 140 may surround the lower portion of the first circuit board 130 and may be electrically connected to the display panel disposed above the first circuit board 130 beyond a lower end of the first circuit board 130.

Since the first circuit board 130 may be disposed under the display panel 110 and the chip on film 140 should be disposed beyond the lower end of the first circuit board 130, a length of a section disposed between the front cover 150 and the first circuit board 130 on the chip on film 140 may increase.

Therefore, a length of the chip on film 140 may be significantly longer than lengths of chip on films in other typical display apparatuses.

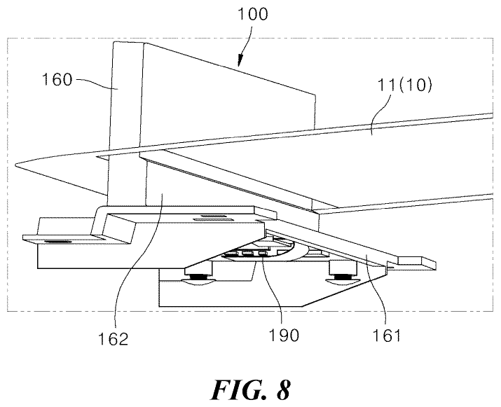

FIG. 8 is a perspective view showing a state in which the display apparatus 100 according to one embodiment is mounted on the dashboard 10 of the vehicle. As shown in FIG. 8, the display apparatus 100 may be mounted on the dashboard 10 of the vehicle.

In this case, the second area 132 of the first circuit board 130 and the accommodation part 162 of the back cover 160 may be disposed inside the dashboard 10. Since the accommodation part 162, which is a relatively thick portion of the display apparatus 100, is disposed inside the dashboard 10, the user may view only the portion exposed to the outside of the display apparatus 100 and cannot view the thick accommodation part 162.

In the display apparatus 100 according to the embodiment, the display panel 110 may be disposed outside the dashboard 10. However, in the display apparatus 100, the accommodation part 162 of the back cover 160, which is disposed under the display panel 110 and is a thick portion, may be disposed inside the dashboard 10.

For example, the dashboard 10 of the vehicle may include an upper cover 11 that forms the upper appearance of the dashboard 10. That is, a lower side of the upper cover 11 may be the inside of the dashboard 10, and the display panel 110 of the display apparatus 100 may be disposed above the upper cover 11.

In an embodiment, the upper cover 11 of the dashboard 10 may be vertically disposed between the accommodation part 162 and the display panel 110. Therefore, the accommodation part 162 is disposed inside the dashboard 10, and the user cannot view the accommodation part 162 of the display apparatus 100.

With this structure, the accommodation part 162 of the thicker back cover 160 of the display apparatus 100 may be hidden by the upper cover 11 of the dashboard 10, and only the slim portion in which the panel 110 is disposed is visible to the user.

Therefore, the display apparatus 100 is perceived by the user as having a slim structure, and the aesthetic sense in design of the display apparatus 100 can be improved.

In addition, in an embodiment, compared to other typical display apparatuses, by arranging the second area 132 of which thickness increases in the first circuit board 130 under the lower end of the display panel 110, the area of the display panel 110 visible to the user cannot be reduced even when the second area 132 is disposed inside the dashboard 10.

Therefore, since the slim appearance of the display apparatus 100 is visible to the user without reducing the area of the display screen, it is possible to provide significant visual convenience to the user.

Meanwhile, referring to FIGS. 5 and 8, the second circuit board 190 may be provided to be attached to the front cover 150 and the back cover 160. The second circuit board 190 may be disposed on the lower portion of the display apparatus 100 and coupled to the front cover 150 and the back cover 160.

The second circuit board 190 may be disposed on the lower portion of the display apparatus 100 generally in a horizontal direction. To mount the second circuit board 190, a first holder 151 and a second holder 161 may be formed on the front cover 150 and the back cover 160, respectively.

The front cover 150 may include the first holder 151 having a space for holding the second circuit board 190 formed in a lower portion thereof. The first holder 151 may be bent at a lower end of the front cover 150 and re-bent at an end thereof to provide the space for holding the second circuit board 190.

The back cover 160 may include the second holder 161 having a space for holding the second circuit board 190 formed in a lower portion thereof. Like the first holder 151, the second holder 161 may be bent at a lower end of the back cover 160 and re-bent at an end thereof to provide the space for holding the second circuit board 190.

The second circuit board 190 may be coupled to the lower portions of the front cover 150 and the back cover 160 using the adhesive tape 260.

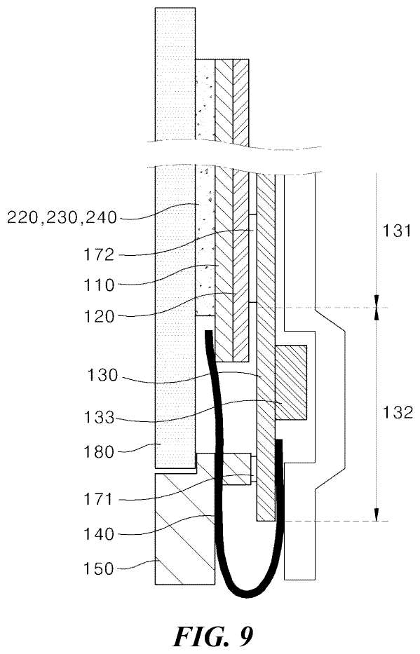

FIG. 9 is a side cross-sectional view schematically showing the display apparatus 100 according to one embodiment. Hereinafter, a structure capable of suppressing the heat generated from the heating element 133 of the first circuit board 130 from being transferred to the display panel 110 will be described with reference to FIG. 9, etc.

An upper area in front of the first circuit board 130 may be coupled to the metal plate 120, and a lower area thereof may be coupled to the front cover 150. With this structure, the lower portion of the first circuit board 130 may be disposed not to overlap the metal plate 120 and the display panel 110 in the front-rear direction.

That is, the heating element 133 provided on the first circuit board 130 may be disposed so as not to overlap at least portions of the metal plate 120 and the display panel 110 in the front-rear direction.

When the heating element 133 overlaps the metal plate 120 and the display panel 110 in the front-rear direction, the heat generated from the heating element 133 may be transferred to the metal plate 120 by conduction, convection, or radiation.

When the heat transferred to the metal plate 120 does not spread smoothly in the metal plate 120, the heat is directly transferred to the display panel 110, and thus the display panel 110 may be overheated at a portion corresponding to the heating element 133 of the display panel 110.

In addition, even when heat spreads smoothly in the metal plate 120, the entirety of the metal plate 120 is in direct contact with the display panel 110, and thus the heat of the metal plate 120 may not be transferred to the display panel 110 by conduction. In this case, the entirety of the display panel 110 may be heated by the heating element 133.

However, in the display apparatus 100 according to the embodiment, with the above-described structure, the heating element 133 may be disposed at a location adjacent to the lower ends of the display panel 110 and the metal plate 120 and thus at least partially may not overlap the display panel 110 and the metal plate 120 in the front-rear direction.

In FIG. 9, in one embodiment, the heating element 133 is disposed to partially overlap the display panel 110 and the metal plate 120 in the front-rear direction. However, according to another embodiment, the heating element 133 may be disposed at a more downward location so that the heating element 133 is vertically disposed under the lower ends of the display panel 110 and the metal plate 120 to prevent the entirety of the heating element 133 from overlapping the display panel 110 and the metal plate 120 in the front-rear direction.

Specifically, the upper area in front of the first circuit board 130 may be disposed to overlap the display panel 110 in the front-rear direction, and the lower area thereof may be disposed to overlap the front cover 150 in the front-rear direction.

From the perspective of the first circuit board 130, in such a structure, at least a portion of the first area 131 may be disposed to overlap the display panel 110 in the front-rear direction, and the second area 132 may be disposed to overlap the front cover 150 in the front-rear direction.

The front cover 150 may be disposed under the display panel 110. Therefore, the front cover 150 may be vertically disposed to be spaced apart from the display panel 110. At least a portion of the heating element 133 may be disposed in a space in which the front cover 150 and the display panel 110 are vertically spaced apart from each other.

Such a spaced space can effectively suppress the heat generated from the heating element 133 from being transferred to the metal plate 120 and the display panel 110 by conduction.

In addition, since at least a portion, specifically, most of the heating element 133 does not overlap the metal plate 120 and the display panel 110 in the front-rear directions, the heat quantity transferred from the heating element 133 to the display panel 110 by radiation or convection can be reduced significantly.

Therefore, it is possible to effectively suppress overheating of the display panel 110 due to heat transfer from the heating element 133 to the display panel 110, prevent damage to the display panel 110 due to heat, and increase the lifetime of the display panel 110.

Meanwhile, the first circuit board 130 may be coupled to each of the front cover 150 and the metal plate 120. For example, the first circuit board 130 may be coupled to each of the front cover 150 and the metal plate 120 by a plurality of adhesive parts 170 disposed to be spaced apart from each other.

As described above, the first circuit board 130 may be coupled to each of the front cover 150 and the metal plate 120 by the plurality of adhesive parts 170 disposed to be spaced apart from each other. As described above, the adhesive part 170 may include the first part 171 and the second part 172. The first part 171 and the second part 172 may be vertically disposed to be spaced apart from each other.

The first part 171 may be disposed on the lower portion of the first circuit board 130 and may couple the first circuit board 130 to the front cover 150. The second part 172 may be disposed on the upper portion of the first circuit board 130 and may couple the first circuit board 130 to the metal plate 120.

As described above, since the first circuit board 130 is coupled to both the front cover 150 and the metal plate 120, the first circuit board 130 may be more fixedly and stably coupled to the display apparatus 100 compared to a conventional case of being the metal plate 120.

Meanwhile, a lower portion of the cover member 180 and an upper portion of the front cover 150 may be disposed to overlap each other in the front-rear direction. For example, a groove in which the lower portion of the cover member 180 is seated may be formed in the front cover 150.

With this structure, the cover member 180 may be seated in the groove of the front cover 150 and stably coupled to the display apparatus 100.

A portion of the lower portion of the cover member 180 may be disposed under the upper cover 11 of the dashboard 10. However, as described above, since the display panel 110 is disposed above the upper cover 11 of the dashboard 10 and the entirety of the display panel 110 is provided outside the dashboard 10, even when a portion of the cover member 180 is provided inside the dashboard 10, the size of the display screen does not decrease.

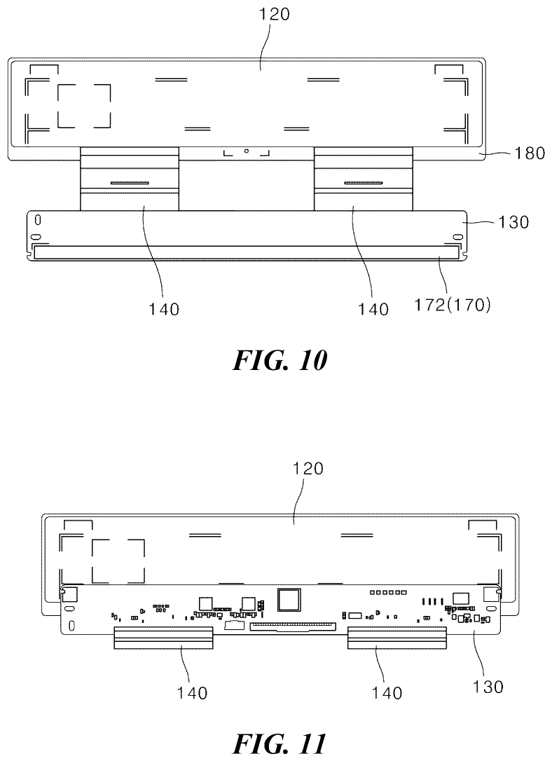

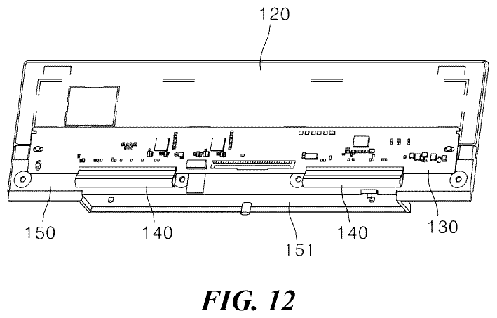

FIG. 10 is a view showing a state in which the chip on film 140 is unfolded in the display apparatus 100 according to one embodiment. FIG. 11 is a view showing a state in which the first circuit board 130 and the metal plate 120 are coupled in the display apparatus 100 according to one embodiment. FIG. 12 is a perspective view of FIG. 11.

To arrange the first circuit board 130 at the designed location, first, both end portions of the chip on film 140 may be attached to the display panel 110 and the first circuit board 130, respectively.

Next, the first circuit board 130 may be attached to a back surface of the front cover 150 and a back surface of the metal plate 120 using the adhesive part 170. In this case, a portion of the chip on film 140 may be bent.

To arrange the heating clement 133 provided on the lower portion of the first circuit board 130 at the location corresponding to the accommodation part 162 of the back cover 160, it is necessary to conduct the work so that the first circuit board 130 is disposed at the designed location of the lower portion of the metal plate 120.

Thereafter, the assembly of the display apparatus 100 may be finished by coupling the front cover 150 and the back cover 160 to other components of the display apparatus 100, and the front cover 150 and the back cover 160 may be coupled to the dashboard 10 of the vehicle, for example, using a coupling tool such as a screw.

A display apparatus according to one embodiment may include a display panel on which a video is displayed, a metal plate disposed behind the display panel, a first circuit board disposed behind the metal plate and electrically connected to the display panel, a chip on film (COF) having one side electrically connected to the display panel, the other side electrically connected to the first circuit board, and a portion provided to be bent, and a front cover disposed in front of the first circuit board and vertically disposed to be spaced apart from the display panel, in which an upper area in front of the first circuit board may be coupled to the metal plate, and a lower area thereof may be coupled to the front cover.

The upper area in front of the first circuit board may be disposed to overlap the display panel in a front-rear direction, and the lower area thereof may be disposed to overlap the front cover in the front-rear direction.

The first circuit board may include a first area having a relatively small thickness and a second area having a relatively great thickness, in which at least a portion of the first area may overlap the display panel in the front-rear direction, and the second area may be disposed to overlap the front cover in the front-rear direction.

The display apparatus may include a back cover of which at least a portion is disposed behind the display panel and the first circuit board, and the back cover may include an accommodation part for accommodating the second area of the first circuit board.

The accommodation part may be formed so that a portion corresponding to the second area of the back cover protrudes from a rear surface of the back cover and is recessed in a front surface of the back cover.

The display apparatus may be provided to be mounted on a dashboard of a vehicle, and the second area and the accommodation part may be disposed inside the dashboard.

A heating element having a higher heating quantity than other elements among the elements constituting the first circuit board may be disposed in the second area.

The heating element may be at least one of a light emitting module, a CPU, and a capacitor.

The chip on film may be disposed to have one side coupled to a lower portion of the first circuit board and the other side coupled to a lower portion of the display panel and vertically disposed to intersect the second area.

At least a portion of the chip on film may be disposed between the front cover and the first circuit board.

The first circuit board may be coupled to each of the front cover and the metal plate by a plurality of adhesive parts disposed to be spaced apart from each other.

The display apparatus may include a cover member disposed in front of the display panel, a second circuit board electrically connected to the first circuit board, and a flexible circuit board electrically connecting the first circuit board to the second circuit board.

A lower portion of the cover member and an upper portion of the front cover may be disposed to overlap each other in a front-rear direction.

The second circuit board may be provided to be attached to the front cover and the back cover, the front cover may include a first holder having a space for holding the second circuit board formed in a lower portion thereof, and the back cover may include a second holder having a space for holding the second circuit board formed in a lower portion thereof.

The display panel may be disposed outside the dashboard.

An upper cover of the dashboard may be vertically disposed between the accommodation part and the display panel.

A display apparatus according to another embodiment may include a display panel on which a video is displayed, a cover member disposed in front of the display panel, a metal plate disposed behind the display panel, a first circuit board disposed behind the metal plate and electrically connected to the display panel, a second circuit board electrically connected to the first circuit board, a chip on film (COF) having one side electrically connected to the display panel, the other side electrically connected to the first circuit board, and a portion provided to be bent, a front cover disposed in front of the first circuit board and vertically disposed to be spaced apart from the display panel, and a back cover of which at least a portion is disposed behind the display panel and the first circuit board, in which an upper area in front of the first circuit board may overlap the display panel in a front-rear direction, and a lower area thereof may be disposed to overlap the front cover in the front-rear direction.

The first circuit board may include a first area having a relatively small thickness and a second area having a relatively great thickness, in which at least a portion of the first area may overlap the display panel in the front-rear direction, and the second area may be disposed to overlap the front cover in the front-rear direction.

The back cover may include an accommodation part for accommodating the second area of the first circuit board, and the accommodation part may be formed so that a portion corresponding to the second area of the back cover protrudes from the rear surface of the back cover and is recessed in a front surface of the back cover.

The display apparatus may be provided to be mounted on a dashboard of a vehicle, and an upper cover of the dashboard may be vertically disposed between the accommodation part and the display panel.

In the display apparatus according to the present disclosure, the accommodation part of the thicker back cover can be hidden by the upper cover of the dashboard, and only the slim portion in which the display panel is disposed of the display apparatus is visible to the user.

Therefore, the display apparatus is perceived by the user as having the slim structure, and the aesthetic sense in design of the display apparatus can be improved.

In addition, in the display apparatus according to the present disclosure, compared to other general display apparatuses, by arranging the second area having the increasing thickness under the lower end of the display panel on the first circuit board, the area of the display panel visible to the user cannot be reduced even when the second area is disposed inside the dashboard.

Therefore, since the slim appearance of the display apparatus is visible to the user without reducing the area of the display screen, it is possible to provide significant visual convenience to the user.

In addition, in the display apparatus according to the present disclosure, since at least some, specifically, most of the heating elements do not overlap the metal plate and the display panel in the front-rear direction, the heat quantity transferred from the heating elements to the display panel can be significantly reduced by radiation or convection.

Therefore, it is possible to effectively suppress the overheating of the display panel due to heat transfer from the heating element to the display panel, prevent the damage to the display panel due to heat, and increase the lifetime of the display panel.

Specific effects together with the above-described effects are described together with a description of the following detailed matters for carrying out the disclosure.

Although the present disclosure has been described above with reference to exemplary drawings, the present disclosure is not limited by the embodiments and drawings disclosed in the specification, and it is apparent that various modifications can be made by those skilled in the art within the scope of the technical spirit of the present disclosure. In addition, even when the operational effects according to the configuration of the present disclosure have not been explicitly described in the description of the embodiments of the present disclosure, it goes without saying that the effects predictable by the corresponding configuration should be recognized.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a display panel configured to display an image;
a metal plate disposed behind the display panel;
a first circuit board disposed behind the metal plate and electrically connected to the display panel;
a chip on film having a first side electrically connected to the display panel and a second side electrically connected to the first circuit board, the chip on film further including a portion configured to be bent; and
a front cover disposed in front of the first circuit board and spaced apart from the display panel in a vertical direction,
wherein an upper area of a front surface of the first circuit board is coupled to the metal plate, and a lower area of the front surface of the first circuit board is coupled to the front cover.

2. The display apparatus of claim 1, wherein the first circuit board has an upper portion overlapping the display panel in a front-rear direction of the display apparatus and a lower portion overlapping the front cover in the front-rear direction.

3. The display apparatus of claim 2, wherein the first circuit board includes a first area and a second area having a greater thickness than the first area, and
at least a portion of the first area is disposed to overlap the display panel in the front-rear direction, and the second area is disposed to overlap the front cover in the front-rear direction.

4. The display apparatus of claim 3, further comprising a back cover, wherein at least a portion of the back cover is disposed behind the display panel and the first circuit board,
wherein the back cover includes an accommodation part configured to accommodate the second area of the first circuit board.

5. The display apparatus of claim 4, wherein the accommodation part includes a portion corresponding to the second area of the back cover that protrudes from a rear surface of the back cover and is recessed in a front surface of the back cover.

6. The display apparatus of claim 5, wherein the display apparatus is configured to be mounted on a dashboard of a vehicle, and
wherein the second area and the accommodation part are disposed inside the dashboard in response to the display apparatus being mounted on the dashboard.

7. The display apparatus of claim 5, wherein the first circuit board further includes a heating element disposed in the second area, wherein the heating element has a higher heating quantity than other elements of the first circuit board.

8. The display apparatus of claim 5, wherein the chip on film is disposed to have the first side coupled to a lower portion of the first circuit board and the second side coupled to a lower portion of the display panel, and wherein the chip on film is vertically disposed to intersect the second area of the first circuit board.

9. The display apparatus of claim 8, wherein at least a portion of the chip on film is disposed between the front cover and the first circuit board.

10. The display apparatus of claim 4, wherein the first circuit board is coupled to each of the front cover and the metal plate by a plurality of adhesive parts disposed to be spaced apart from each other.

11. The display apparatus of claim 6, wherein the display panel is disposed outside the dashboard in response the display apparatus being mounted on the dashboard.

12. The display apparatus of claim 11, wherein an upper cover of the dashboard is vertically disposed between the accommodation part and the display panel.

13. The display apparatus of claim 7, wherein the heating element is at least one of a light emitting module, a CPU, and a capacitor.

14. A display apparatus, comprising:
a display panel configured to display an image;
a metal plate disposed behind the display panel;
a first circuit board disposed behind the metal plate and electrically connected to the display panel;
a chip on film having a first side electrically connected to the display panel and a second side electrically connected to the first circuit board, the chip on film further including a portion configured to be bent;
a front cover disposed in front of the first circuit board and spaced apart from the display panel in a vertical direction;
a cover member in front of the display panel;
a second circuit board electrically connected to the first circuit board; and
a flexible circuit board electrically connecting the first circuit board to the second circuit board,
wherein an upper area of a front surface of the first circuit board is coupled to the metal plate, and a lower area of the front surface of the first circuit board is coupled to the front cover.

15. The display apparatus of claim 14, wherein a lower portion of the cover member and an upper portion of the front cover are disposed to overlap each other in the front-rear direction.

16. The display apparatus of claim 14, wherein the second circuit board is attached to the front cover and the back cover,
the front cover includes a first holder in a lower portion of the front cover, the first holder including a space configured to hold the second circuit board, and
the back cover includes a second holder in a lower portion of the back cover, the second holder including a space configured to hold the second circuit board.

17. A display apparatus comprising:
a display panel configured to display an image;
a cover member in front of the display panel;
a metal plate disposed behind the display panel;
a first circuit board disposed behind the metal plate and electrically connected to the display panel;
a second circuit board electrically connected to the first circuit board;
a chip on film having a first side electrically connected to the display panel and a second side electrically connected to the first circuit board, the chip of film further including a portion configured to be bent;
a front cover disposed in front of the first circuit board and spaced apart from the display panel in a vertical direction; and
a back cover, wherein at least a portion of the back cover is disposed behind the display panel and the first circuit board,
wherein an upper area of a front surface of the first circuit board overlaps the display panel in a front-rear direction of the display apparatus, and a lower area of the front surface of the first circuit board overlaps the front cover in the front-rear direction.

18. The display apparatus of claim 17, wherein the first circuit board includes a first area and a second area having a greater thickness than the first area, and
at least a portion of the first area is disposed to overlap the display panel in the front-rear direction, and the second area is disposed to overlap the front cover in the front-rear direction.

19. The display apparatus of claim 18, wherein the back cover includes an accommodation part configured to accommodate the second area of the first circuit board, and
the accommodation part includes a portion corresponding to the second area of the back cover that protrudes from a rear surface of the back cover and is recessed in a front surface of the back cover.

20. The display apparatus of claim 19. wherein the display apparatus is configured to be mounted on a dashboard of a vehicle, and
wherein an upper cover of the dashboard is vertically disposed between the accommodation part and the display panel.
